(19) United States
(12) Patent Application Publication
(10) Pub. No.: US 2008/0303026 A1
(43) Pub. Date: Dec. 11, 2008

(54) SEMICONDUCTOR DEVICE AND METHOD FOR MANUFACTURING THE DEVICE

(76) Inventor: Doo-Sung Lee, Taebaek-si (KR)

Correspondence Address: SHERR & VAUGHN, PLLC, 620 HERNDON PARKWAY, SUITE 200, HERNDON, VA, 20170, US

(21) Appl. No.: 12/134,887

(22) Filed: Jun. 6, 2008

(30) Foreign Application Priority Data
Jun. 8, 2007 (KR) 10-2007-0055862

(51) Int. Cl. H01L 21/28; H01L 29/04

(52) U.S. Cl. 257/65; 438/592; 257/E29.003; 257/E21.19

(57) ABSTRACT

A semiconductor device and a method for manufacturing the same that includes forming a gate insulating film on a semiconductor substrate; and then forming a doped polysilicon layer on the gate insulating film; and then forming a first metal layer on the doped polysilicon layer; and then forming a metal silicide layer on the first metal layer. Therefore, current leakage can be reduced and generation of boron penetration can be prevented. Forming the doped polysilicon layer on the gate insulating film enables control of a work function while forming a silicide layer having a uniform surface interface is possible by depositing nickel (Ni) and polysilicon on the platinum first metal layer.

The present application claims priority under 35 U.S.C. 119 to Korean Patent Application No. 10-2007-0055862 (filed on Jun. 8, 2007), which is hereby incorporated by reference in its entirety.

### BACKGROUND

The use of a poly Si gate in a highly integrated semiconductor device can generally exhibit problems such as high gate resistance, poly depletion, and boron penetration, etc. and thus, has led to the use of gates formed from other materials such as metals, etc. However, use of gate materials such as pure TiN, TaN and TiSiN, etc., the work function of an NMOS or PMOS is rarely changed so that a fully silicide silicon gate composed by forming a silicide on and/or over the gate has been used. When manufacturing the fully silicide silicon gate using Ni silicide, an interface between the silicon and the silicide is not flat, thereby causing problems that deteriorate the properties of the gate and increase resistance. Moreover, when using metal or silicide as the gate, work function is not controlled by doping but is fixed at a predetermined value. Therefore, in order to control work function of the NMOS and PMOS, other metals or silicides should be used, respectively, thereby causing complicating the fabrication process.

### SUMMARY

Embodiments relate to a semiconductor device and a method for manufacturing the device having fully silicide silicon gate that reduces current leakage and prevents generation of boron penetration.

Embodiments relate to a semiconductor device and a method for manufacturing the device having fully silicide silicon gate that can optionally control work function by forming a doped poly silicon layer on and/or over the uppermost surface of a gate insulating film.

Embodiments relate to a semiconductor device and a method for manufacturing the device having fully silicide silicon gate with a silicide layer having flat interface.

Embodiments relate to a semiconductor device that can include at least one of the following: a semiconductor substrate having a device isolating film; a gate insulating film formed on and/or over the semiconductor substrate; a doped poly silicon layer formed on and/or over an uppermost surface of the gate insulating film; a first metal layer formed on and/or over an uppermost surface of the doped poly silicon layer; and a metal silicide layer formed on and/or over an uppermost surface of the first metal layer.

Embodiments relate to a method for manufacturing a semiconductor device that can include at least one of the following steps: forming a gate insulating film on and/or over a semiconductor substrate having a device isolating film; and then forming a doped polysilicon layer on and/or over an uppermost surface of the gate insulating film; and then forming a first metal layer on and/or over an uppermost surface of the doped polysilicon layer; and then forming a second metal layer on and/or over an uppermost surface of the first metal layer; and then forming a polysilicon layer on and/or over an uppermost surface of the second metal layer; and then causing a reaction between the second metal layer and the poly silicon layer to form a metal silicide layer by performing an annealing on the semiconductor substrate.

Embodiments relate to a method for manufacturing a semiconductor device that can include at least one of the following steps: forming a gate insulating film on a semiconductor substrate; and then forming a doped polysilicon layer on the gate insulating film; and then forming a first metal layer on the doped polysilicon layer; and then forming a metal silicide layer on the first metal layer.

### DRAWINGS

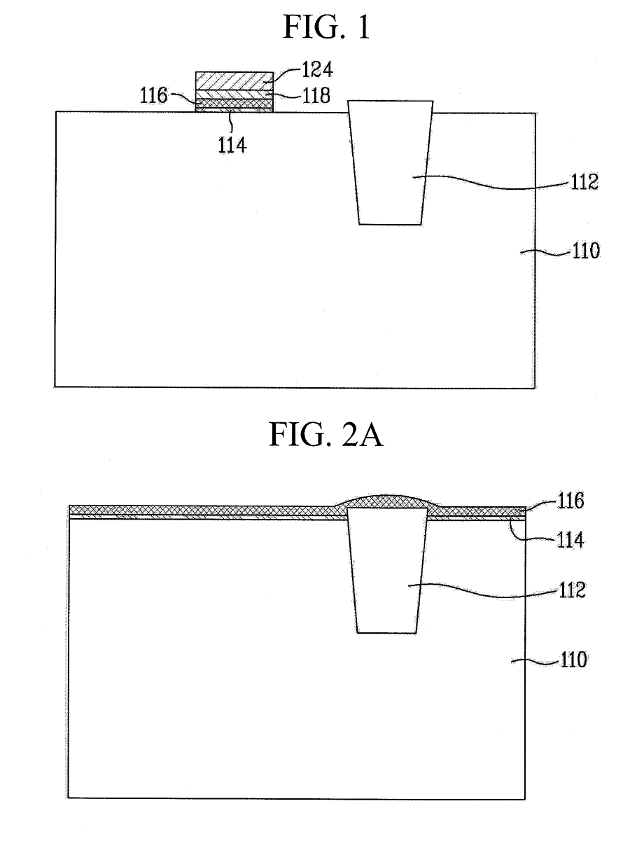

Example FIG. 1 illustrates a fully silicide silicon gate in accordance with embodiments.

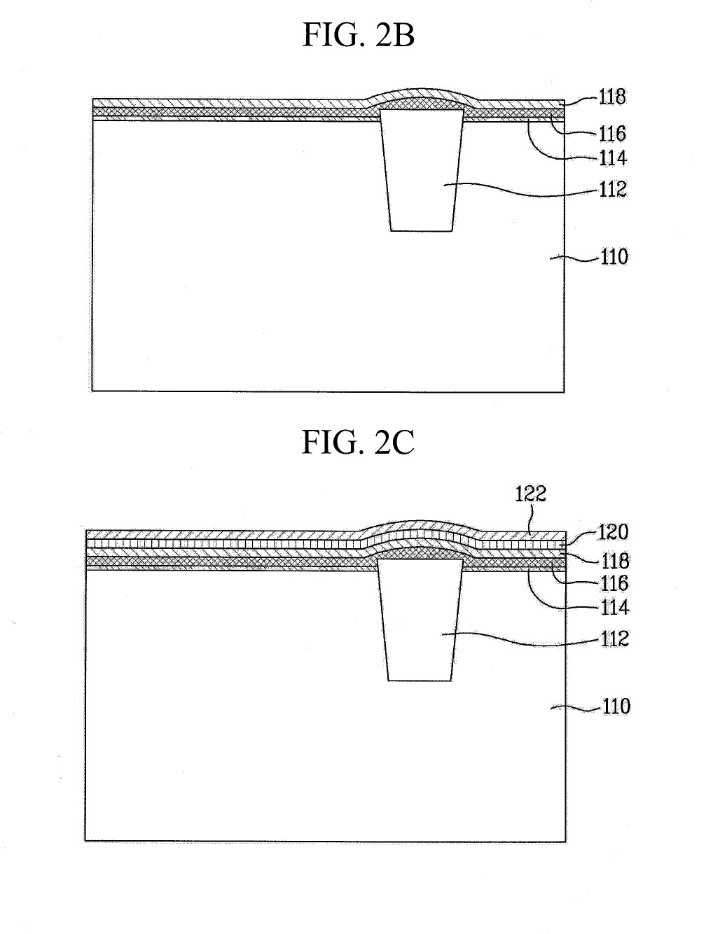

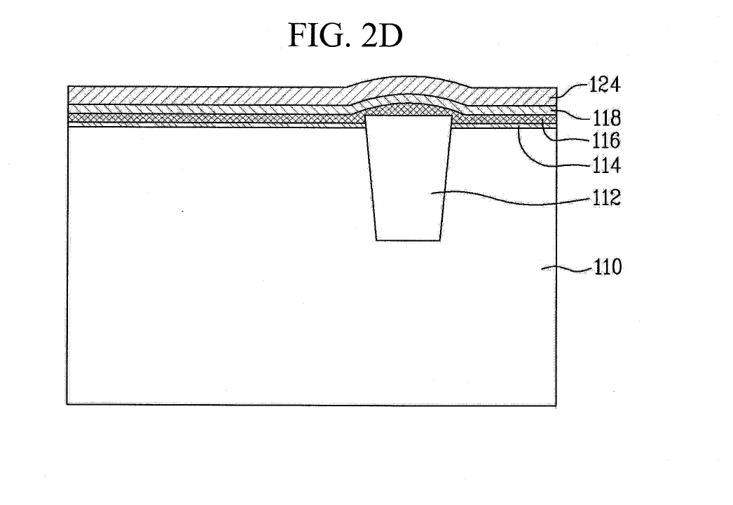

Example FIGS. 2A to 2D illustrate a method for manufacturing a fully silicide silicon gate in accordance with embodiments.

### DESCRIPTION

As illustrated in example FIG. 1, a semiconductor device in accordance with embodiments can include a fully silicide silicon gate having gate insulating film 114 formed on and/or over semiconductor substrate 110 formed with device isolating film 112, doped poly silicon layer 116 formed on and/or over an uppermost surface of gate insulating film 114, first metal layer 118 formed on and/or over an uppermost surface of doped poly silicon layer 116, and metal silicide layer 124 formed on and/or over an uppermost surface of first metal layer 118. Device isolating film 112 functions to mutually isolate a plurality of devices that are different from each other. Gate insulating film 114 may be composed of a nitrided oxide. Doped polysilicon layer 116 can be doped with arsenic (As). First metal layer 118 may be composed of platinum (Pt) and metal silicide layer 124 can be composed of nickel silicide (Ni-Silicide).

As illustrated in example FIG. 2A, a method for manufacturing a fully silicide silicon gate in accordance with embodiments can include forming a pad nitride film on and/or over semiconductor substrate 110 and patterning the pad nitride film through photo and etching processes in order to expose a device isolating region. The exposed substrate regions are then etched using the patterned pad nitride film as a mask to form a trench. An insulating film is then deposited in order to gap-fill the trench. The insulating film is grinded through a chemical mechanical polishing process to a predetermined thickness to form device isolating film 112. Thereafter, the pad nitride film is removed by performing an etching. A silicon oxide (SiOx) layer is formed on and/or over semiconductor substrate 110 formed with device isolating film 112. The SiOx layer may be formed having a thickness of between 14 Å to 20 Å. Preferably, the SiOx layer is formed having a thickness of 16 Å. The SiOx layer may then be nitrified in a decoupled plasma nitridation (DPN) method that can easily nitrify the SiOx layer to form gate insulating film 114 composed of a nitrided oxide.

Doped polysilicon layer 116 may be formed on and/or over an uppermost surface of gate insulating film 114 by forming a polysilicon layer doped with arsenic having a thickness of between 400 Å to 600 Å. Preferably doped polysilicon layer 116 may have a thickness of 500 Å. The method for manufacturing the polysilicon layer may be divided into a low temperature process and a high temperature process according to the process temperature. The high temperature process may have a process temperature of around 1000° C., may require a temperature condition above a modification temperature of the insulating substrate. Therefore, in the high temperature process, since heat resistance of a glass substrate is deteriorated, there is a disadvantage in that an expensive quartz substrate having high heat resistance should be used. Moreover, a polysilicon thin film formed using such a high temperature process has a disadvantage in that the device application characteristics thereof is worse than those of the polysilicon by using a low temperature process, due to high surface roughness and low grade crystallinity such as refined crystal grains when forming a film. Therefore, it has been studied/developed a technique that forms polysilicon by crystallizing it through using amorphous silicon capable of low temperature deposition. The high temperature process may be a solid phase crystallization (SPC) method while the low temperature process can be at least one of a laser annealing method and a metal induced crystallization (MIC) method, etc. The SPC method is a method for forming polysilicon by annealing amorphous silicon at a high temperature for a long period of time. The laser annealing method is a method of growing polysilicon by applying a laser to a substrate deposited with an amorphous silicon thin film. The MIC method is a method for forming polysilicon by depositing metal on amorphous silicon.

As illustrated in example FIG. 2B, platinum (Pt) may be deposited on and/or over an uppermost surface of doped poly silicon layer 116 to form first metal layer 118.

As illustrated in example FIG. 2C, second metal layer 120 composed of a metal such as nickel may then be deposited on and/or over an uppermost surface of first metal layer 118. Second metal layer 120 may have a thickness of between 400 Å to 600 Å. Preferably, second metal layer 120 may have a thickness of 500 Å. Polysilicon layer 122 may then be on and/or over an uppermost surface of second metal layer 120. Polysilicon layer 122 may have a thickness of between 800 Å to 1000 Å. Preferably, polysilicon layer 122 may have a thickness of 900 Å.

As illustrated in example FIG. 2D, polysilicon layer 122 can react with second metal layer 120 through an annealing process to form metal silicide layer 124. Particularly, the nickel (Ni) in second metal layer 120 has a specific resistance of 6 μΩcm, which reacts with the silicon (Si) in polysilicon layer 122 to form a substance having very low specific resistance. Such a substance where metal reacts with silicon is referred to as silicide, of which its most important object is to increase speed by reducing RC delay in a logic device. The nickel silicide may be composed of NiSi (mono-silicide) having a low specific resistance and NiSi₂ (di-silicide) having high specific resistance. The nickel silicide has an advantage in that silicide having low specific resistance can be obtained through a rapid thermal processing at one time in the low temperature. As described above, first metal layer 118, which is composed of platinum (Pt), may be provided in accordance with embodiments beneath second metal layer 120, thereby making it possible to prevent diffusion into other layers thereunder when performing the annealing process for forming metal silicide layer 124.

The semiconductor device manufacturing in accordance with embodiments is advantageous by reducing current leakage and also preventing the generation of boron penetration. Formation of a doped polysilicon layer on an uppermost surface of a gate insulating film enables control of work function. Formation of a silicide having a uniform surface interface can be achieved by depositing nickel (Ni) and polysilicon on an uppermost surface of a platinum layer (Pt).

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a semiconductor substrate having a device isolating film;
a gate insulating film formed on the semiconductor substrate;
a doped polysilicon layer formed on and contacting the gate insulating film;
a first metal layer formed on and contacting the doped polysilicon layer; and
a metal silicide layer formed on and contacting the first metal layer.

2. The semiconductor device of claim 1, wherein the doped polysilicon layer is doped with arsenic.

3. The semiconductor device of claim 2, wherein the doped polysilicon layer has a thickness of between 400 Å to 600 Å.

4. The semiconductor device of claim 1, wherein the gate insulating layer is composed of a nitride oxide.

5. The semiconductor device of claim 4, wherein the gate insulating layer has a thickness of between 14 Å to 20 Å.

6. The semiconductor device of claim 4, wherein the gate insulating layer has a thickness of 16 Å.

7. The semiconductor device of claim 1, wherein the first metal layer is composed of platinum.

8. The semiconductor device of claim 1, wherein the metal silicide layer is composed of nickel silicide (Ni-silicide).

9. The semiconductor device of claim 1, wherein the metal silicide layer is formed by a reaction between a second metal layer and a polysilicon layer.

10. The semiconductor device of claim 9, wherein the second metal layer is composed of nickel.

11. The semiconductor device of claim 10, wherein the second metal layer has a thickness of between 400 Å to 600 Å and the polysilicon layer has a thickness of between 800 Å to 1000 Å.

12. The semiconductor device of claim 10, wherein the second metal layer has a thickness of 500 Å and the polysilicon layer has a thickness of 900 Å.

13. A method for manufacturing a semiconductor device comprising:
forming a gate insulating film on a semiconductor substrate having a device isolating film; and then
forming a doped polysilicon layer on and contacting the gate insulating film; and then
forming a first metal layer on and contacting the doped polysilicon layer; and then
forming a second metal layer on and contacting the first metal layer; and then
forming a polysilicon layer on and contacting the second metal layer; and then
forming a metal silicide layer by causing a reaction between the second metal layer and the polysilicon layer by performing an annealing on the semiconductor substrate.

14. The method of claim 13, wherein forming the gate insulating film comprises:
forming a silicon oxide layer on the semiconductor substrate; and then
nitrifying the silicon oxide layer using a decoupled plasma nitridation method to form a gate insulating film composed of a nitrided oxide.

15. The method of claim 13, wherein forming the doped polysilicon layer comprises:
forming a polysilicon layer on the gate insulating film; and then
doping the polysilicon layer with arsenic.

16. The method of claim 13, wherein the first metal layer is composed of platinum.

17. The method of claim 13, wherein the second metal layer is composed of nickel.

18. The method of claim 13, wherein the metal silicide layer is composed of nickel silicide.

19. A method for manufacturing a semiconductor device comprising:
forming a gate insulating film on a semiconductor substrate; and then
forming a doped polysilicon layer on the gate insulating film; and then
forming a first metal layer on the doped polysilicon layer; and then
forming a metal silicide layer on the first metal layer.

20. The method of claim 19, wherein forming the metal silicide comprises:
forming a second metal layer on the first metal layer; and then
forming a polysilicon layer on the second metal layer; and then
performing an annealing process causing a reaction between the second metal layer and the polysilicon layer to form the metal silicide layer.
